(19) United States
(12) Patent Application Publication
(10) Pub. No.: US 2012/0228757 A1
(43) Pub. Date: Sep. 13, 2012

(54) COOLING STRUCTURE OF SEMICONDUCTOR DEVICE

(75) Inventors: Akio Kitami, Toyota-shi (JP); Takashi Ueno, Toyota-shi (JP)

(73) Assignee: TOYOTA JIDOSHA KABUSHIKI KAISHA, Toyota-shi, Aichi-ken (JP)

(21) Appl. No.: 13/511,305

(22) PCT Filed: Nov. 25, 2009
(86) PCT No.: PCT/JP2009/069825

§ 371 Date: May 22, 2012

(51) Int. Cl. H01L 23/36

(52) U.S. Cl. 257/713

(57) ABSTRACT

A cooling structure of a semiconductor device includes an output electrode, a semiconductor element and a semiconductor element disposed to face each other with the output electrode interposed therebetween, a radiator disposed for the semiconductor element on a side opposite to the output electrode, and a radiator disposed for the semiconductor element on the side opposite to the output electrode. The output electrode includes an element mounting portion and a heat transport portion. The element mounting portion is electrically connected to the semiconductor element and the semiconductor element, and is formed of a conductive material. The heat transport portion is disposed to extend from the element mounting portion toward the radiator and the radiator. With this structure, a cooling structure of a semiconductor device with which excellent cooling efficiency is realized can be provided.

### TECHNICAL FIELD

This invention generally relates to a cooling structure of a semiconductor device, and more particularly to a cooling structure of a semiconductor device that is applied to an inverter mounted on a vehicle.

### BACKGROUND ART

With regard to a conventional cooling structure of a semiconductor device, Japanese Patent Laying-Open No. 2008-42074, for example, discloses a semiconductor device for preventing the device from becoming larger (PTL1). The semiconductor device disclosed in PTL1 has a first semiconductor element and a second semiconductor element, a first radiator stacked on the first semiconductor element with a first power substrate interposed therebetween, and a second radiator stacked on the second semiconductor element with a second power substrate interposed therebetween.

Moreover, Japanese Patent Laying-Open No. 4-7860 discloses a semiconductor stack that can be assembled with a smaller number of parts and can also achieve reduction in size and weight (PTL2). The semiconductor stack disclosed in PTL2 includes a heat pipe type radiator wherein one end of a heat pipe is embedded in a heat-receiving block and a radiator fin is attached to the other end of the heat pipe. A plurality of the heat pipe type radiators having such a structure and a plurality of semiconductor elements are stacked on one another to form a sandwich structure.

### CITATION LIST

### Patent Literature

PTL 1: Japanese Patent Laying-Open No. 2008-42074
PTL 2: Japanese Patent Laying-Open No. 4-7860

### SUMMARY OF INVENTION

### Technical Problem

Operation of a semiconductor element used for an inverter circuit or the like involves generation of an extremely large amount of heat, and thus, various types of cooling structures have been adopted. In the semiconductor device disclosed in PTL1, however, no member is disposed between the first semiconductor element and the second semiconductor element to shut off or radiate the heat generated from each semiconductor element. For this reason, the heat generated from the first semiconductor element and the heat generated from the second semiconductor element interfere with each other, resulting in a possibility that sufficient cooling efficiency cannot be achieved.

Accordingly, an object of this invention is to solve the above-described problem and to provide a cooling structure of a semiconductor device with which excellent cooling efficiency is realized.

### Solution To Problem

A cooling structure of a semiconductor device according to this invention includes an electrode, a first semiconductor element and a second semiconductor element disposed to face each other with the electrode interposed therebetween, a first radiator disposed for the first semiconductor element on a side opposite to the electrode, and a second radiator disposed for the second semiconductor element on the side opposite to the electrode. The electrode includes an element mounting portion and a heat transport portion. The element mounting portion is electrically connected to the first semiconductor element and the second semiconductor element, and is formed of a conductive material. The heat transport portion is provided to extend from the element mounting portion toward the first radiator and the second radiator.

According to the cooling structure of a semiconductor device structured as above, heat generated from the first semiconductor element and the second semiconductor element can be transferred to the first radiator and the second radiator through the transport portion. In this way, the efficiency in cooling the first semiconductor element and the second semiconductor element can be improved.

Preferably, the heat transport portion extends from the element mounting portion in a direction orthogonal to a direction in which the first semiconductor element and the second semiconductor element face each other. The heat transport portion is formed of a thermal conductivity anisotropic member whose heat transfer coefficient in a direction in which the heat transport portion extends is greater than that in the direction in which the first semiconductor element and the second semiconductor element face each other.

According to the cooling structure of a semiconductor device structured as above, since the heat transfer coefficient of the heat transport portion in the direction in which the first semiconductor element and the second semiconductor element face each other is small, interference between the heat generated from the first semiconductor element and the heat generated from the second semiconductor element can be effectively suppressed. Moreover, since the heat transfer coefficient of the heat transport portion in its extending direction is great, the heat generated from the first semiconductor element and the second semiconductor element can be efficiently transferred to the first radiator and the second radiator through the heat transport portion.

Preferably, the thermal conductivity anisotropic member is formed of a heat pipe or oriented graphite. According to the cooling structure of a semiconductor device structured as above, the thermal conductivity anisotropic member whose heat transfer coefficient in the direction in which the heat transport portion extends is greater than that in the direction in which the semiconductor elements face each other is constructed from the heat pipe or the oriented graphite.

Preferably, the heat transport portion is formed of an insulating material with high thermal conductive characteristics. The heat transport portion is provided to be interposed between each of the first radiator and the second radiator and the element mounting portion. According to the cooling structure of a semiconductor device structured as above, the heat transport portion can provide electrical isolation between each of the first radiator and the second radiator and a conductive portion.

Preferably, the element mounting portion is a bus bar formed of copper or aluminum. The heat transport portion is formed of aluminum nitride or a resin with high thermal conductive characteristics, which is formed to cover the bus bar. According to the cooling structure of a semiconductor device structured as above, the aluminum nitride or the resin with high thermal conductive characteristics can provide electrical isolation between each of the first radiator and the second radiator and the bus bar formed of copper or aluminum.

Preferably, the electrode is formed of a conductive material with high thermal conductive characteristics in such a manner that the element mounting portion and the heat transport portion are integral with each other. According to the cooling structure of a semiconductor device structured as above, the electrode having both functions of conducting current to the semiconductor elements and of transferring heat with high efficiency can be realized with a simple structure.

Preferably, the heat transport portion has a heat-receiving portion disposed in a position where the first semiconductor element and the second semiconductor element face each other, and receiving heat generated from the first semiconductor element and the second semiconductor element, and a radiating portion disposed in a space between the first radiator and the second radiator, and radiating heat transferred from the heat-receiving portion. The heat transport portion extends from the heat-receiving portion toward the radiating portion. According to the cooling structure of a semiconductor device structured as above, the heat generated from the first semiconductor element and the second semiconductor element is transferred from the heat-receiving portion to the radiating portion, resulting in improved efficiency in cooling the first semiconductor element and the second semiconductor element.

Preferably, the element mounting portion is provided to cover the radiating portion in a space between the first radiator and the second radiator. The cooling structure of a semiconductor device further includes an insulating substrate provided to be interposed between the first semiconductor element and the element mounting portion, and the first radiator, and between the second semiconductor element and the element mounting portion, and the second radiator. According to the cooling structure of a semiconductor device structured as above, the insulating substrate can provide electrical isolation between the first semiconductor element and the element mounting portion, and the first radiator, and between the second semiconductor element and the element mounting portion, and the second radiator.

Preferably, the insulating substrate is provided such that a portion interposed between the first semiconductor element and the first radiator and a portion interposed between the element mounting portion and the first radiator are divided from each other, and such that a portion interposed between the second semiconductor element and the second radiator and a portion interposed between the element mounting portion and the second radiator are divided from each other. According to the cooling structure of a semiconductor device structured as above, breakage of the insulating substrate caused by thermal strain due to a change in temperature can be suppressed.

### Advantageous Effects of Invention

As described above, according to this invention, a cooling structure of a semiconductor device with which excellent cooling efficiency is realized can be provided.

### BRIEF DESCRIPTION OF DRAWINGS

FIG. 1 is a diagram schematically showing a drive unit of a hybrid vehicle.

FIG. 2 is an electric circuit diagram showing a configuration of a PCU shown in FIG. 1.

FIG. 3 is a cross-sectional view showing a cooling structure of a semiconductor device that is applied to an inverter shown in FIG. 2.

FIG. 4 is a cross-sectional view showing the cooling structure of the semiconductor device along the line IV-IV shown in FIG. 3.

FIG. 5 is a cross-sectional view showing a first modification of the cooling structure of a semiconductor device shown in FIG. 3.

FIG. 6 is a cross-sectional view showing a second modification of the cooling structure of a semiconductor device shown in FIG. 3.

FIG. 7 is a cross-sectional view showing a third modification of the cooling structure of a semiconductor device shown in FIG. 3.

FIG. 8 is a cross-sectional view showing a cooling structure of a semiconductor device according to a second embodiment of this invention.

### DESCRIPTION OF EMBODIMENTS

Embodiments of this invention will be described with reference to the drawings. In the drawings referred to below, identical or corresponding members are denoted by the same numbers.

### First Embodiment

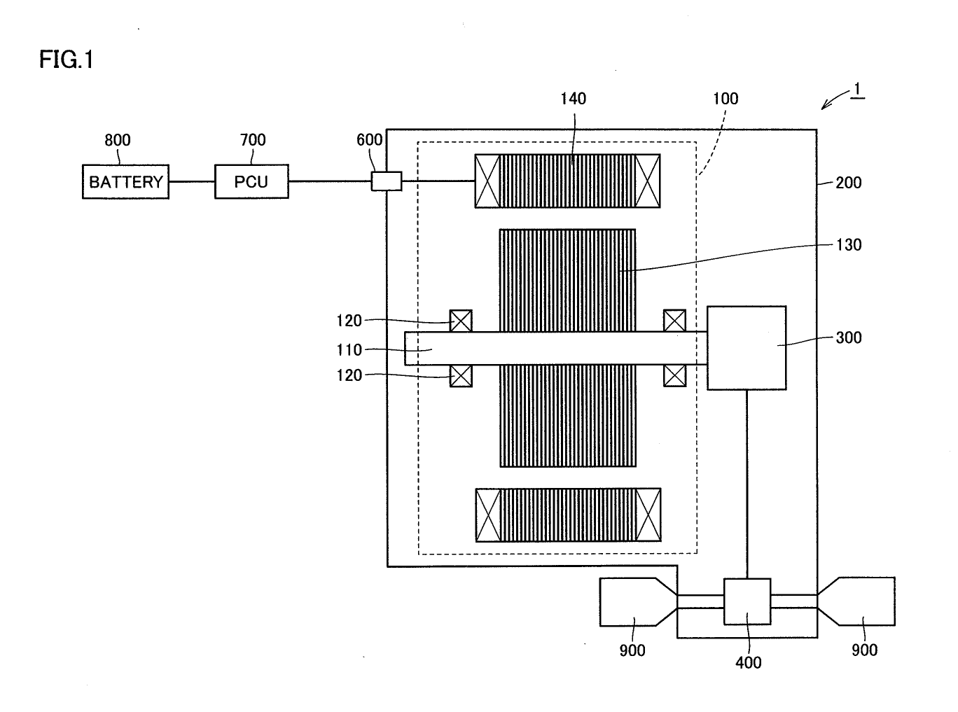

FIG. 1 is a diagram schematically showing a drive unit of a hybrid vehicle. In the present embodiment, the present invention is applied to an inverter mounted on a hybrid vehicle corresponding to a vehicle. An HV system for driving the hybrid vehicle is described first.

With reference to FIG. 1, a drive unit 1 is provided in the hybrid vehicle having, as motive power sources, an internal combustion engine such as a gasoline engine, a diesel engine, or the like, and a chargeable and dischargeable battery 800. Drive unit 1 is configured to include a motor generator 100, a housing 200, a reduction mechanism 300, a differential mechanism 400, a driveshaft receiving portion 900, and a terminal block 600.

Motor generator 100 is a rotating electric machine that functions as a motor or an electric power generator. Motor generator 100 includes a rotating shaft 110, a rotor 130, and a stator 140. Rotating shaft 110 is rotatably attached to housing 200 with a bearing 120 interposed therebetween. Rotor 130 rotates integrally with rotating shaft 110.

Motive power output from motor generator 100 is transmitted from reduction mechanism 300 to driveshaft receiving portion 900 via differential mechanism 400. Driving force transmitted to driveshaft receiving portion 900 is transmitted as rotating force to a wheel via a driveshaft, causing the vehicle to travel.

On the other hand, during regenerative braking of the hybrid vehicle, the wheel is rotated by inertia force of the vehicle body. Motor generator 100 is driven by the rotating force from the wheel via driveshaft receiving portion 900, differential mechanism 400, and reduction mechanism 300. At this time, motor generator 100 operates as an electric power generator. Electric power generated by motor generator 100 is supplied to battery 800 via a PCU (Power Control Unit) 700.

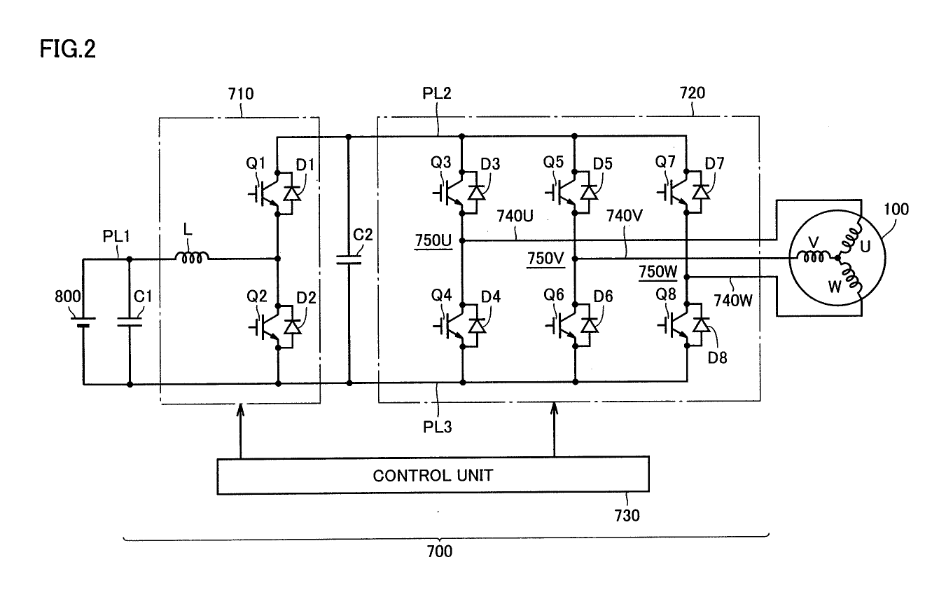

FIG. 2 is an electric circuit diagram showing a configuration of the PCU shown in FIG. 1. With reference to FIG. 2, PCU 700 includes a converter 710, an inverter 720, a control unit 730, capacitors C1, C2, power supply lines PL1 to PL3, and output lines 740U, 740V and 740W.

Converter 710 is connected with battery 800 via power supply lines PL1 and PL3. Inverter 720 is connected with converter 710 via power supply lines PL2 and PL3. Inverter 720 is connected with motor generator 100 via output lines 740U, 740V and 740W. Battery 800 is a DC power supply and formed of a secondary battery, for example, a nickel-metal hydride battery, a lithium-ion battery, or the like. Battery 800 supplies DC power stored therein to converter 710 or is charged with DC power received from converter 710.

Converter 710 includes an upper arm and a lower arm each constituted of a semiconductor module, and a reactor L. The upper arm and lower arm are connected in series between power supply lines PL2 and PL3. The upper arm connected to power supply line PL2 is formed of a power transistor (IGBT: Insulated Gate Bipolar Transistor) Q1 and a diode D1 connected in antiparallel with power transistor Q1. The lower arm connected to power supply line PL3 is formed of a power transistor Q2 and a diode D2 connected in antiparallel with power transistor Q2. Reactor L is connected between power supply line PL1 and a connection point between the upper arm and the lower arm.

Converter 710 up-converts DC voltage received from battery 800 using reactor L, and supplies the up-converted voltage to power supply line PL2. Converter 710 down-converts DC voltage received from inverter 720, and charges battery 800.

Inverter 720 includes a U-phase arm 750U, a V-phase arm 750V, and a W-phase arm 750W. U-phase arm 750U, V-phase arm 750V, and W-phase arm 750W are connected in parallel between power supply lines PL2 and PL3. Each of U-phase arm 750U, V-phase arm 750V, and W-phase arm 750W is formed of an upper arm and a lower arm, each constituted of a semiconductor module. The upper arm and lower arm of each phase arm are connected in series between power supply lines PL2 and PL3.

The upper arm of U-phase arm 750U is formed of a power transistor (IGBT) Q3 and a diode D3 connected in antiparallel with power transistor Q3. The lower arm of U-phase arm 750U is formed of a power transistor Q4 and a diode D4 connected in antiparallel with power transistor Q4. The upper arm of V-phase arm 750V is formed of a power transistor Q5 and a diode D5 connected in antiparallel with power transistor Q5. The lower arm of V-phase arm 750V is formed of a power transistor Q6 and a diode D6 connected in antiparallel with power transistor Q6. The upper arm of W-phase arm 750W is formed of a power transistor Q7 and a diode D7 connected in antiparallel with power transistor Q7. The lower arm of W-phase arm 750W is formed of a power transistor Q8 and a diode D8 connected in antiparallel with power transistor Q8. A connection point of the power transistors of each phase arm is connected to a side opposite to a neutral point, of a coil of the corresponding phase of motor generator 100 via corresponding output line 740U, 740V, or 740W.

The figure shows the case where each of the upper arm and the lower arm of each of U-phase arm 750U to W-phase arm 750W is constituted of a single semiconductor module formed of a power transistor and a diode; however, each of the upper and lower arms may also be constituted of a plurality of semiconductor modules.

Inverter 720 converts DC voltage received from power supply line PL2 to AC voltage based on a control signal from control unit 730, and outputs the AC voltage to motor generator 100. Inverter 720 rectifies the AC voltage generated by motor generator 100 to DC voltage, and supplies the DC voltage to power supply line PL2.

Capacitor C1 is connected between power supply lines PL1 and PL3 to smooth a voltage level of power supply line PL1. Capacitor C2 is connected between power supply lines PL2 and PL3 to smooth a voltage level of power supply line PL2.

Control unit 730 calculates a coil voltage of each phase of motor generator 100 based on a torque command value and a current value of each phase of motor generator 100, as well as input voltage of inverter 720. Based on a result of calculation, control unit 730 generates a PWM (Pulse Width Modulation) signal by which power transistors Q3 to Q8 are turned ON/OFF, and outputs the PWM signal to inverter 720. The current value of each phase of motor generator 100 is detected by a current sensor incorporated in the semiconductor module constituting each arm of inverter 720. This current sensor is placed within the semiconductor module so that an SN ratio is improved. Control unit 730 calculates a duty ratio of each of power transistors Q1 and Q2 for optimizing the input voltage of inverter 720, based on the above-described torque command value and the number of revolutions of the motor. Based on the result, control unit 730 generates a PWM signal by which power transistors Q1 and Q2 are turned ON/OFF, and outputs the signal to converter 710.

Control unit 730 controls switching operation of power transistors Q1 to Q8 in converter 710 and inverter 720 in order to convert the AC voltage generated by motor generator 100 to DC voltage to charge battery 800.

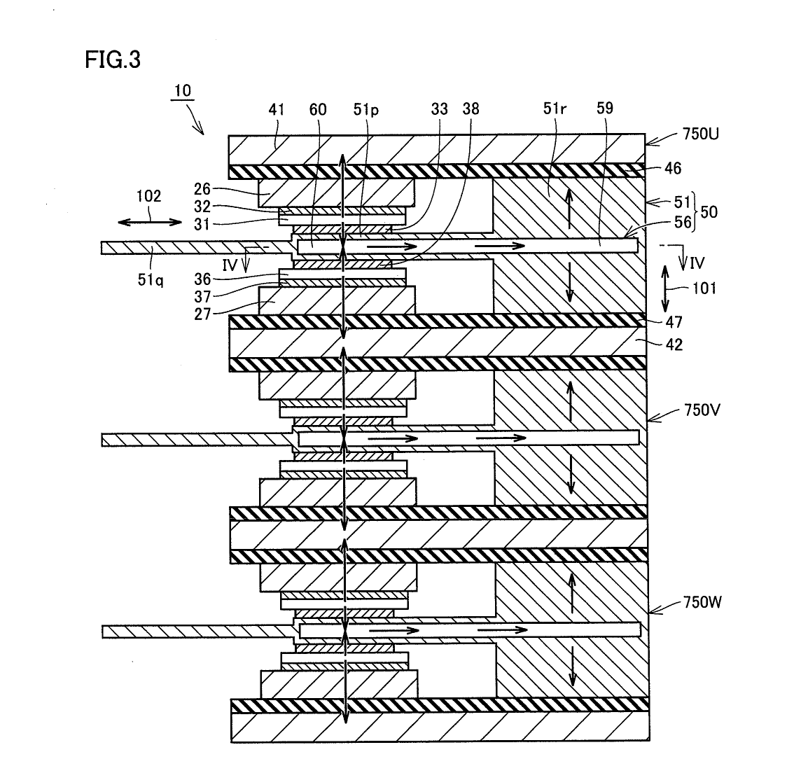

Next, a cooling structure of a semiconductor device according to the present embodiment will be described in detail. FIG. 3 is a cross-sectional view showing a cooling structure of a semiconductor device that is applied to the inverter shown in FIG. 2.

With reference to FIG. 3, there is shown a semiconductor device 10 formed by stacking U-phase arm 750U, V-phase arm 750V, and W-phase arm 750W on one another in one direction. Since each phase arm has the same structure, the cooling structure of semiconductor device 10 according to the present embodiment will hereinafter be described, with attention being focused on U-phase arm 750U representatively.

The cooling structure of semiconductor device 10 according to the present embodiment mainly has a semiconductor element 31 and a semiconductor element 36 configured to include power transistor (IGBT) Q3 and power transistor Q4 in FIG. 2, respectively, an input electrode 26 and an input electrode 27, an output electrode 50, and a radiator 41 and a radiator 42.

Semiconductor element 31 and semiconductor element 36 are disposed to face each other at a distance from each other, in a direction indicated by an arrow 101 (the direction indicated by arrow 101 is hereinafter also referred to as the direction in which semiconductor element 31 and semiconductor element 36 face each other).

Output electrode 50 is connected to output line 740U shown in FIG. 2, using, for example, a connector or wiring not illustrated. Output electrode 50 is disposed between semiconductor element 31 and semiconductor element 36. In other words, semiconductor element 31 and semiconductor element 36 are disposed so as to sandwich output electrode 50 from opposing sides. Output electrode 50 is connected to semiconductor element 31 with solder 33, and is connected to semiconductor element 36 with solder 38.

Output electrode 50 is formed to extend in a direction indicated by an arrow 102, which is orthogonal to the direction in which semiconductor element 31 and semiconductor element 36 face each other. When semiconductor device 10 is viewed in the direction in which semiconductor element 31 and semiconductor element 36 face each other, output electrode 50 is formed to extend in the form of a band in the direction indicated by arrow 102. Output electrode 50 is formed to extend from a position where semiconductor element 31 and semiconductor element 36 face each other, in one direction orthogonal to the direction in which semiconductor element 31 and semiconductor element 36 face each other, and in a direction opposite thereto.

Input electrode 26 is disposed such that semiconductor element 31 is positioned between input electrode 26 and output electrode 50. Input electrode 26 is connected to semiconductor element 31 with solder 32. Input electrode 26 is connected to power supply line PL2 shown in FIG. 2, using, for example, a connector or wiring not illustrated. Input electrode 27 is disposed such that semiconductor element 36 is positioned between input electrode 27 and output electrode 50. Input electrode 27 is connected to semiconductor element 36 with solder 37. Input electrode 27 is connected to power supply line PL3 shown in FIG. 2, using, for example, a connector or wiring not illustrated.

Input electrode 26 and input electrode 27 are disposed in parallel. This cancels out a parasitic inductance between input electrode 26 and input electrode 27, thus enabling reduced switching loss.

Radiator 41 is disposed for semiconductor element 31 on a side opposite to output electrode 50. Radiator 41 is disposed such that input electrode 26 is positioned between radiator 41 and semiconductor element 31. Radiator 41 is connected to input electrode 26 with insulating substrate 46 interposed therebetween. Radiator 46 is disposed for semiconductor element 36 on the side opposite to output electrode 50. Radiator 46 is disposed such that input electrode 27 is positioned between radiator 46 and semiconductor element 36. Radiator 46 is connected to input electrode 27 with insulating substrate 47 interposed therebetween.

Radiators 41, 42 are formed to extend from the position where semiconductor element 31 and semiconductor element 36 face each other, in one direction orthogonal to the direction in which semiconductor element 31 and semiconductor element 36 face each other. Radiators 41, 42 are constituted of a cooling oil passage through which a cooling oil serving as a coolant circulates, and radiator fins disposed on the cooling oil passage and formed of a metal having high thermal conductive characteristics, for example, aluminum.

The structure of radiators 41, 42 is not particularly limited, and may also be of an air-cooling type, for example.

Insulating substrate 46 is formed of a plate-shaped member made of an insulating material. Insulating substrate 46 is formed of, for example, insulating ceramic. Insulating substrate 46 is connected to input electrode 26 and radiator 41 by brazing, for example. Insulating substrate 47 is connected to input electrode 27 and radiator 42 by brazing, for example.

In the cooling structure of semiconductor device 10 according to the present embodiment, one semiconductor element 31 is disposed between radiator 41 and output electrode 50, and one semiconductor element 36 is disposed between radiator 42 and output electrode 50. U-phase arm 750U and V-phase arm 750V are provided so as to share one radiator at a boundary between them, and V-phase arm 750V and W-phase arm 750W are provided so as to share one radiator at a boundary between them.

Output electrode 50 is structured to have an element mounting portion 51 and a heat transport portion 56.

Element mounting portion 51 is formed of a conductive material such as copper. Element mounting portion 51 is provided so as to be electrically connected with semiconductor elements 31, 36. That is, semiconductor elements 31, 36 are mounted on element mounting portion 51 with solder 33 and 38, respectively. Element mounting portion 51 has a current-conducting function by which semiconductor elements 31, 36 are electrically connected to output line 740U, which is external wiring.

Heat transport portion 56 is provided to extend toward radiators 41, 42 from element mounting portion 51 having semiconductor elements 31, 36 mounted thereon. Heat transport portion 56 extends, from element mounting portion 51 having semiconductor elements 31, 36 mounted thereon, in the direction indicated by arrow 102, which is orthogonal to the direction in which semiconductor element 31 and semiconductor element 36 face each other (the direction indicated by arrow 102 is also hereinafter referred to as the direction in which heat transport portion 56 extends). Heat transport portion 56 extends, from element mounting portion 51 having semiconductor elements 31, 36 mounted thereon, in a direction away from the position where semiconductor element 31 and semiconductor element 36 face each other. Heat transport portion 56 extends in parallel with radiators 41, 42. Heat transport portion 56 has a heat transfer function by which heat generated from semiconductor elements 31, 36 is transferred toward radiators 41, 42.

Heat transport portion 56 has a heat-receiving portion 60 disposed in the position where semiconductor element 31 and semiconductor element 36 face each other, and a radiating portion 59 disposed in a space between radiator 41 and radiator 42. Heat transport portion 56 extends from heat-receiving portion 60 toward radiating portion 59. Heat-receiving portion 60 receives the heat generated from semiconductor elements 31, 36, and radiating portion 59 releases the heat transferred from heat-receiving portion 60 toward radiating portions 41, 42.

In the direction in which heat transport portion 56 extends, heat transport portion 56 has a heat transfer coefficient greater than that of element mounting portion 51. In the cooling structure of semiconductor device 10 according to the present embodiment shown in FIG. 3, heat transport portion 56 has a heat transfer coefficient greater than that of element mounting portion 51 in the direction in which heat transport portion 56 extends.

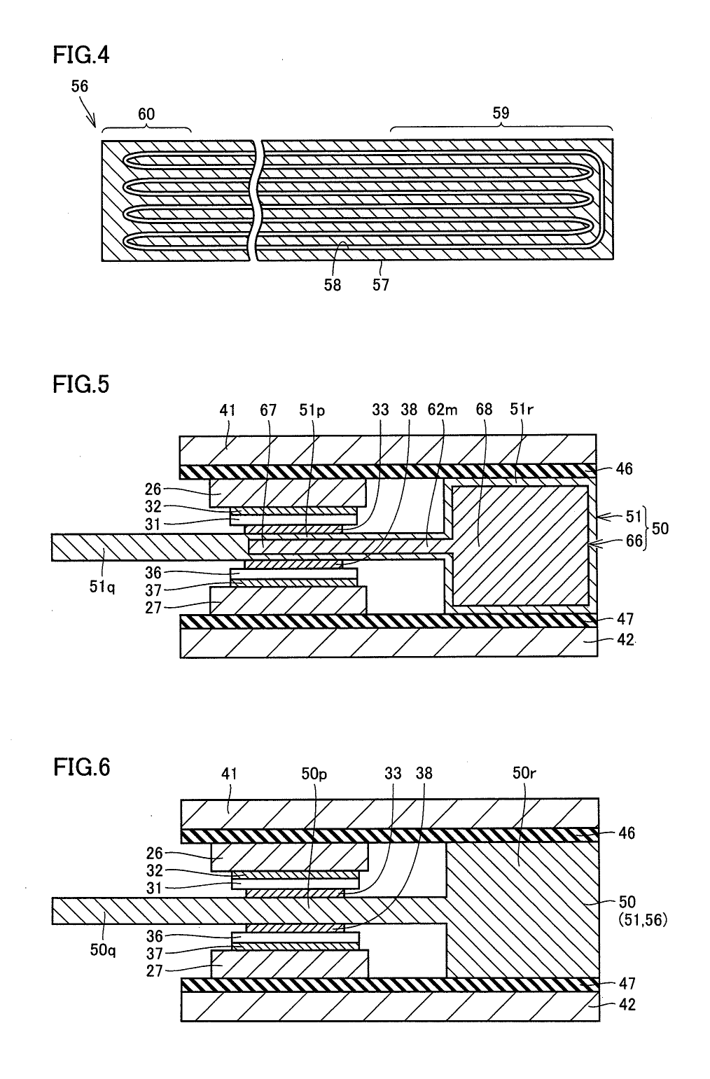

FIG. 4 is a cross-sectional view showing the heat transport portion along the line IV-IV shown in FIG. 3. With reference to FIGS. 3 and 4, heat transport portion 56 is formed of a thermal conductivity anisotropic member whose heat transfer coefficient in the direction in which heat transport portion 56 extends is greater than that in the direction in which semiconductor element 31 and semiconductor element 36 face each other. In the present embodiment, a self-excitation type heat pipe is used as the thermal conductivity anisotropic member.

A structure of the self-excitation type heat pipe is now described. Heat transport portion 56 has a metal plate 57 in which a heat medium path 58 is formed. Metal plate 57 is formed of a metal such as aluminum, copper, stainless steel, or the like. Heat medium path 58 is formed inside metal plate 57 in a state sealed under vacuum. Heat medium path 58 extends between heat-receiving portion 60 and radiating portion 59. Heat medium path 58 extends as it meanders within a plane in which metal plate 57 extends, forming a closed path (loop hole).

Sealed inside heat medium path 58 is a heat medium such as water, Freon, ethanol, ammonia, or the like. The heat medium is sealed at a volume ratio of, for example, 50% with respect to heat medium path 58.

In the self-excitation type heat pipe having such a structure, owing to a pumping effect resulting from a pressure rise caused by evaporation of the coolant in heat-receiving portion 60 and a pressure drop caused by condensation of steam in radiating portion 59, heat is transported as the coolant vibrates between heat-receiving portion 60 and radiating portion 59. For this reason, as compared to the case of a heat pipe that employs a wick structure, the transported heat includes, in addition to latent heat generated by evaporation of the coolant in heat-receiving portion 60, sensible heat generated by transfer of the liquid coolant, and therefore, a high transport capability can be exhibited. There is also an advantage of less influence of installation position, as compared to the heat pipe that employs a wick structure.

Heat medium path 58 constituted of a self-excitation type heat pipe has such characteristics that a heat transfer coefficient in a thickness direction of metal plate 57 is smaller than that in a surface direction thereof, and for example, the heat transfer coefficient in the surface direction is approximately from 800 to several 1000 W/mK, while the heat transfer coefficient in the thickness direction is not more than one tenth thereof (aluminum: 200 W/mK, copper: 400 W/mK).

While a self-excitation type heat pipe is used as heat transport portion 56 in the present embodiment, a heat pipe having a wick structure may also be used.

With reference to FIG. 3, element mounting portion 51 has a joint portion 51p, an externally connected portion 51q, and a heat transfer portion 51r. Joint portion 51p is disposed in the position where semiconductor element 31 and semiconductor element 36 face each other. Semiconductor element 31 and semiconductor element 36 are joined to joint portion 51p with solder 33 and solder 38, respectively. Joint portion 51p is provided to cover heat-receiving portion 60.

Externally connected portion 51q and heat transfer portion 51r are disposed such that joint portion 51p is positioned between them in the direction in which heat transport portion 56 extends. Externally connected portion 51q is connected with a connector or wiring not illustrated, whereby element mounting portion 51 is electrically connected to output line 740U shown in FIG. 2. Heat transfer portion 51r is provided to cover radiating portion 59 and fill a space between radiator 41 and radiator 46. Heat transfer portion 51r is connected to radiator 41 with insulating substrate 46 interposed therebetween, and connected to radiator 42 with insulating substrate 47 interposed therebetween. This provides electrical isolation between radiators 41, 42 and heat transfer portion 51r.

Heat transport portion 51r has a thick structure having a thickness greater than that in joint portion 51p and that in externally connected portion 51q.

Next, a function and effect achieved by the cooling structure of semiconductor device 10 according to the present embodiment will be described.

In FIG. 3, paths of the heat generated from semiconductor elements 31 and 36 are indicated by the arrows. With reference to FIG. 3, operation of inverter 720 shown in FIG. 2 involves a large amount of heat generated from semiconductor elements 31 and 36. In the cooling structure of semiconductor device 10 according to the present embodiment, the heat generated from semiconductor elements 31, 36 is transferred to heat-receiving portion 60 of heat transport portion 56 through solder 33, 38 and joint portion 51p of element mounting portion 51. The thermal conductivity anisotropic member forming heat transport portion 56 has such characteristics that the heat transfer coefficient in the thickness direction is smaller than that in the direction in which heat transport portion 56 extends. Therefore, a phenomenon in which the heat generated from semiconductor element 31 and the heat generated from semiconductor element 36 interfere with each other can be effectively suppressed.

The thermal conductivity anisotropy of heat transport portion 56 allows the heat transferred to heat-receiving portion 60 to be transferred efficiently from heat-receiving portion 60 to radiating portion 59. The heat transferred to radiating portion 59 is further transferred through heat transfer portion 51r of element mounting portion 51 to radiators 41 and 42, where it is radiated by exchange of heat with the cooling oil inside radiators 41 and 42.

In addition to the above-described heat path, the heat generated from semiconductor element 31 is transferred to radiator 41 through input electrode 26 and the heat generated from semiconductor element 36 is transferred to radiator 42 through input electrode 27. Consequently, a double-sided cooling effect of cooling each of semiconductor elements 31, 36 from both surface sides can be achieved.

Moreover, the cooling structure of semiconductor device 10 according to the present embodiment is realized by output electrode 50, which is an integral part having the current-conducting function of element mounting portion 51 and the heat transfer function of heat transport portion 56. This reduces the number of parts in semiconductor device 10, leading to reduction in its manufacturing cost.

The above-described basic features of the cooling structure of semiconductor device 10 according to the first embodiment of this invention will be described in summary. The cooling structure of semiconductor device 10 according to the present embodiment includes output electrode 50 corresponding to an electrode, semiconductor element 31 corresponding to a first semiconductor element and semiconductor element 36 corresponding to a second semiconductor element, which are disposed to face each other with output electrode 50 interposed therebetween, radiator 41 corresponding to a first radiator, which is disposed for semiconductor element 31 on the side opposite to output electrode 50, and radiator 42 corresponding to a second radiator, which is disposed for semiconductor 36 on the side opposite to output electrode 50. Output electrode 50 includes element mounting portion 51 and heat transport portion 56. Element mounting portion 51 is electrically connected to semiconductor element 31 and semiconductor element 36, and is formed of a conductive material. Heat transport portion 56 is disposed to extend from element mounting portion 51 toward radiator 41 and radiator 42.

According to the cooling structure of semiconductor device 10 in the first embodiment of this invention structured as above, semiconductor element 31 and semiconductor element 36 are disposed on both sides of output electrode 50 interposed therebetween, and output electrode 50 is provided with heat transport portion 56, thereby achieving improved efficiency in cooling semiconductor elements 31 and 36.

It is noted that the stacked structure of U-phase arm 750U, V-phase arm 750V, and W-phase arm 750W shown in FIG. 3 is by way of example only, and for example, a structure in which semiconductor devices are further stacked on one another, or a structure in which a plurality of arms are aligned in a plane orthogonal to the direction in which semiconductor element 31 and semiconductor element 36 face each other may also be adopted.

Next, various modifications of the cooling structure of semiconductor device 10 shown in FIG. 3 will be described. FIG. 5 is a cross-sectional view showing a first modification of the cooling structure of a semiconductor device shown in FIG. 3.

With reference to FIG. 5, in the present modification, output electrode 50 is structured to have a heat transport portion 66 instead of heat transport portion 56 shown in FIG. 3.

Heat transport portion 66 has a heat-receiving portion 67 disposed in the position where semiconductor element 31 and semiconductor element 36 face each other, and a radiating portion 68 disposed in a space between radiator 41 and radiator 42, and extends from heat-receiving portion 67 toward radiating portion 68. Heat transport portion 66 is formed of a thermal conductivity anisotropic member whose heat transfer coefficient in the direction in which heat transport portion 66 extends is greater than that in the direction in which semiconductor element 31 and semiconductor element 36 face each other. In the present embodiment, graphite with high thermal conductive characteristics is used as the thermal conductivity anisotropic member. Graphite with high thermal conductive characteristics is used as a material having a dense two-dimensional crystal structure and exhibiting remarkably improved phonon heat conduction in the surface direction.

While FIG. 5 shows heat transport portion 66 formed to have a large thickness in radiating portion 68, the thick portion of radiating portion 68 may be replaced with the metal that forms element mounting portion 51 where heat transfer portion 51r of element mounting portion 51 has a heat transfer coefficient smaller than that in a thickness direction of the graphite with high thermal conductive characteristics.

FIG. 6 is a cross-sectional view showing a second modification of the cooling structure of a semiconductor device shown in FIG. 3. With reference to FIG. 6, in the present modification, output electrode 50 is formed of a conductive material with high thermal conductive characteristics in such a manner that element mounting portion 51 and heat transport portion 56 are integral with each other. Such a conductive material with high thermal conductive characteristics may, for example, be copper.

A more specific structure is now described. Output electrode 50 has a joint portion 50p on a heat-receiving side, which is disposed in a position where semiconductor element 31 and semiconductor element 36 face each other, a heat transfer portion 50r on a radiating side, which is provided so as to fill a space between radiator 41 and radiator 46, and an externally connected portion 50q, which is disposed on a side opposite to heat transfer portion 50r with respect to joint portion 50p, and is connected with, for example, a connector or wiring not illustrated.

Heat generated from semiconductor elements 31, 36 is transferred to joint portion 50p through solder 33, 38. The heat transferred to joint portion 50p is transferred to heat transfer portion 50r and radiated by radiators 41, 42. Output electrode 50, on the other hand, is formed of a conductive material, and therefore ensures electrical conduction between semiconductor elements 31, 36 and the outside through joint portion 50p and externally connected portion 50q.

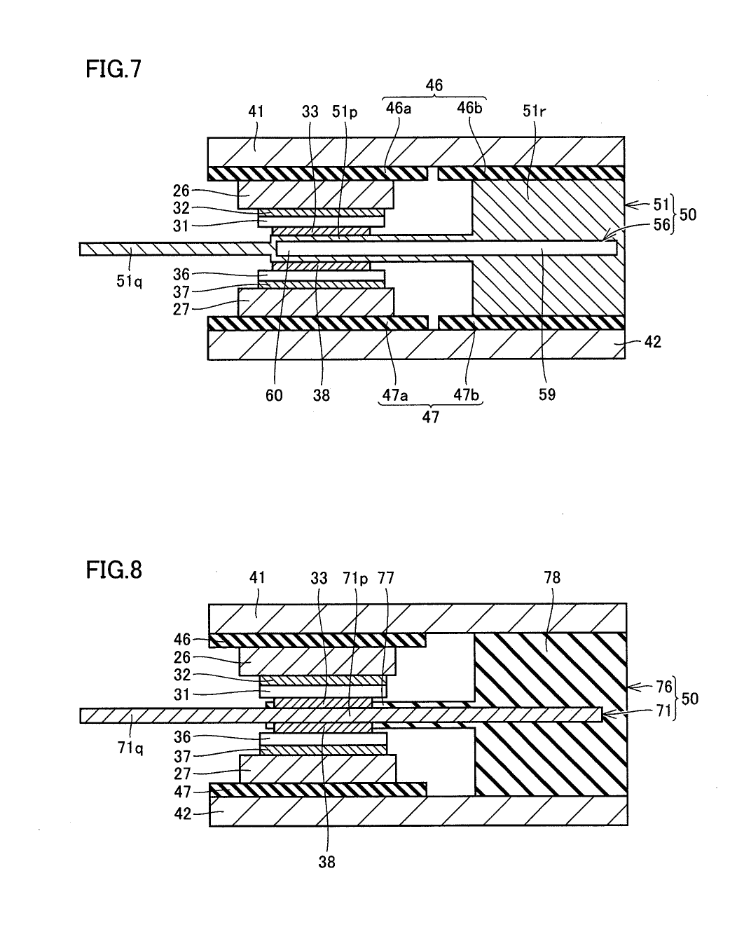

FIG. 7 is a cross-sectional view showing a third modification of the cooling structure of a semiconductor device shown in FIG. 3. With reference to FIG. 7, in the present modification, insulating substrate 46 is constituted of a first portion 46a and a second portion 46b divided from first portion 46a, and insulating substrate 47 is constituted of a first portion 47a and a second portion 47b divided from first portion 47a. First portion 46a is interposed between input electrode 26 and radiator 41, and second portion 46b is interposed between element mounting portion 51 and radiator 41. First portion 47a is interposed between input electrode 27 and radiator 42, and second portion 47b is interposed between element mounting portion 51 and radiator 42.

In insulating substrates 46, 47 connected to radiators 41, 42 and input electrodes 26, 27, strain is generated by thermal deformation of these connected parts, which may cause breakage of insulating substrates 46, 47. Such a problem becomes noticeable particularly where brazing is used to fix insulating substrates 46, 47, because insulating substrates 46, 47 are fixed firmly. In contrast, in the present modification, a divided structure is adopted for each of insulating substrates 46, 47 to keep the size of each substrate small, thereby preventing breakage of insulating substrates 46, 47 more reliably.

### Second Embodiment

FIG. 8 is a cross-sectional view showing a cooling structure of a semiconductor device according to a second embodiment of this invention. The cooling structure of the semiconductor device according to the present embodiment basically has the same structure as that of the cooling structure of semiconductor device 10 according to the first embodiment. The description of identical structural portions will not be repeated hereinbelow.

With reference to FIG. 8, in the present embodiment, output electrode 50 is structured to have an element mounting portion 71 and a heat transport portion 76.

Element mounting portion 71 is provided as a bus bar formed of copper or aluminum. Element mounting portion 71 has a joint portion 71p, which is disposed in a position where semiconductor element 31 and semiconductor element 36 face each other, and to which semiconductor elements 31, 36 are joined with solder 33, 38. Element mounting portion 7 also has an externally connected portion 71q provided in a portion extending further from joint portion 71 in one direction and connected with, for example, a connector or wiring not illustrated.

Heat transport portion 76 is formed of an insulating material with high thermal conductive characteristics. One example of such a material may be aluminum nitride (AlN). Other examples include a resin with high thermal conductive characteristics, for example, a resin containing, as an inorganic filler with thermal conductive characteristics, an oxide such as alumina, silica, zinc oxide, magnesia, or the like, or a nitride such as silicon nitride, boron nitride, aluminum nitride, or the like.

Heat transport portion 76 has a heat-receiving portion 77 that is provided to be connected with joint portion 71p and receives heat generated from semiconductor elements 31, 36 and a radiating portion 78 that is disposed in a space between radiator 41 and radiator 42 and radiates heat transferred from heat-receiving portion 77. Heat transport portion 76 extends from heat-receiving portion 77 toward radiating portion 78. The heat generated from semiconductor elements 31, 36 is transferred to heat-receiving portion 77 through solder 33, 38. The heat transferred to heat-receiving portion 77 is transferred to radiating portion 78 through heat transport portion 76 and is radiated by radiators 41, 42.

Radiating portion 78 of heat transport portion 76 has a block shape having a thickness larger than that of heat-receiving portion 77. In the present embodiment, since heat transport portion 76 is formed of an insulating material, radiating portion 78 is provided in direct contact with radiators 41, 42 without insulating substrates 46, 47 interposed therebetween.

With this structure, insulating substrate 46 should only be interposed between input electrode 26 and radiator 41, and insulating substrate 47 be interposed between input electrode 27 and radiator 42, thereby keeping the size of each of insulating substrates 46, 47 small. In this way, breakage of insulating substrates 46, 47 due to thermal strain can be suppressed. Further, because of the large thickness of radiating portion 78 between radiator 41 and radiator 42, withstand voltage of heat transport portion 76 can be set to be low.

With the cooling structure of the semiconductor device according to the second embodiment of this invention structured as above, the same effects as those described in the first embodiment can be obtained.

It is noted that the elements of the cooling structures of semiconductor devices according to the embodiments and modifications described above may be combined as appropriate, to form a new cooling structure of a semiconductor device.

Moreover, the present invention is also applicable to a reactor mounted on a fuel cell hybrid vehicle (FCHV) that uses a fuel cell and a secondary battery as motive power sources, or an electric vehicle (EV). In the hybrid vehicle according to the present invention, the internal combustion engine is driven at an operating point where fuel efficiency is optimal, whereas in a fuel cell hybrid vehicle, the fuel cell is driven at an operating point where power generation efficiency is optimal. How the secondary battery is used is basically the same in both hybrid vehicles.

It should be understood that the embodiments disclosed herein are illustrative and non-restrictive in every respect. The scope of the present invention is defined by the terms of the claims, rather than by the foregoing description, and is intended to include any modifications within the scope and meaning equivalent to the terms of the claims.

### INDUSTRIAL APPLICABILITY

This invention is applied to various types of power modules, in addition to a power converter mounted on a vehicle.

### REFERENCE SIGNS LIST

10: semiconductor device, 26, 27: input electrode, 31, 36: semiconductor element, 41, 42: radiator, 46, 47: insulating substrate, 46a, 47a: first portion, 46b, 47b: second portion, 50: output electrode, 50p, 51p, 71p: joint portion, 50q, 51q, 71q: externally connected portion, 50r, 51r: heat transfer portion, 51, 71: element mounting portion, 56, 66, 76: heat transport portion, 57: metal plate, 58: heat medium path, 59, 68, 78: radiating portion, 60, 67, 77: heat-receiving portion, 100: motor generator, 110: rotating shaft, 120: bearing, 130: rotor, 140: stator, 200: housing, 300: reduction mechanism, 400: differential mechanism, 600: terminal block, 710: converter, 720: inverter, 730: control unit, 740U, 740V, 740W: output line, 750U: U-phase arm, 750V: V-phase arm, 750W: W-phase arm.

1. A cooling structure of a semiconductor device comprising:
an electrode;
a first semiconductor element and a second semiconductor element disposed to face each other with said electrode interposed therebetween;
a first radiator disposed for said semiconductor element on a side opposite to said electrode; and
a second radiator disposed for said second semiconductor element on the side opposite to said electrode,
said electrode including an element mounting portion electrically connected to said first semiconductor element and said second semiconductor element and formed of a conductive material, and a heat transport portion provided to extend from said element mounting portion toward said first radiator and said second radiator.

2. The cooling structure of a semiconductor device according to claim 1, wherein
said heat transport portion extends from said element mounting portion in a direction orthogonal to a direction in which said first semiconductor element and said second semiconductor element face each other, and
said heat transport portion is formed of a thermal conductivity anisotropic member whose heat transfer coefficient in a direction in which said heat transport portion extends is greater than that in the direction in which said first semiconductor element and said second semiconductor element face each other.

3. The cooling structure of a semiconductor device according to claim 2, wherein
said thermal conductivity anisotropic member is formed of a heat pipe or oriented graphite.

4. The cooling structure of a semiconductor device according to claim 1, wherein
said heat transport portion is formed of an insulating material with high thermal conductive characteristics, and is provided to be interposed between each of said first radiator and said second radiator and said element mounting portion.

5. The cooling structure of a semiconductor device according to claim 4, wherein
said element mounting portion is a bus bar formed of copper or aluminum, and
said heat transport portion is formed of aluminum nitride or a resin with high thermal conductive characteristics, which is formed to cover said bus bar.

6. The cooling structure of a semiconductor device according to claim 1, wherein
said electrode is formed of a conductive material with high thermal conductive characteristics in such a manner that said element mounting portion and said heat transport portion are integral with each other.

7. The cooling structure of a semiconductor device according to claim 1, wherein
said heat transport portion has a heat-receiving portion disposed in a position where said first semiconductor element and said second semiconductor element face each other, and receiving heat generated from said first semiconductor element and said second semiconductor element, and
a radiating portion disposed in a space between said first radiator and said second radiator, and radiating heat transferred from said heat-receiving portion, and
said heat transport portion extends from said heat-receiving portion toward said radiating portion.

8. The cooling structure of a semiconductor device according to claim 7, wherein
said element mounting portion is provided to cover said radiating portion in a space between said first radiator and said second radiator, and
said cooling structure of a semiconductor device further comprises an insulating substrate provided to be interposed between said first semiconductor element and said element mounting portion, and said first radiator, and between said second semiconductor element and said element mounting portion, and said second radiator.

9. The cooling structure of a semiconductor device according to claim 8, wherein
said insulating substrate is provided such that a portion interposed between said first semiconductor element and said first radiator and a portion interposed between said element mounting portion and said first radiator are divided from each other, and such that a portion interposed between said second semiconductor element and said second radiator and a portion interposed between said element mounting portion and said second radiator are divided from each other.
